(19) United States
(12) Patent Application Publication
(10) Pub. No.: US 2025/0336795 A1
(43) Pub. Date: Oct. 30, 2025

(54) PACKAGE STRUCTURE

(71) Applicant: inergy Technology Inc., Hsinchu County (TW)

(72) Inventors: Li-Zheng LIN, Hsinchu County (TW); Nan-Wei WEN, Hsinchu County (TW)

(21) Appl. No.: 19/189,299

(22) Filed: Apr. 25, 2025

(30) Foreign Application Priority Data
Apr. 25, 2024 (TW) 113204190

(51) Int. Cl. H01L 23/498; H01L 23/00

(52) U.S. Cl. CPC H01L 23/49838; H01L 24/37; H01L 24/38; H01L 2224/37013; H01L 2224/38

(57) ABSTRACT

A package structure includes a substrate, a chip, a first electrically conductive piece and a second electrically conductive piece. The chip is disposed on the substrate. The first electrically conductive piece includes a first electrically conductive portion and at least one first pin. The first pin is connected with the first electrically conductive portion. The first electrically conductive portion is connected with the chip. The first pin is away from the chip. The second electrically conductive piece includes a second electrically conductive portion and at least one second pin. The second pin is connected with the second electrically conductive portion. The second electrically conductive portion is connected with the chip. The second pin is away from the chip. At least one of the first electrically conductive piece and the second electrically conductive piece is an integrally formed structure.

### RELATED APPLICATIONS

This application claims priority to Taiwanese Application Serial Number 113204190, filed Apr. 25, 2024, which is herein incorporated by reference in its entirety.

### BACKGROUND

### Technical Field

The present disclosure relates to package structures.

### Description of Related Art

As the living standards of people continue to rise, electronic products have become increasingly important in daily life. In response to the enormous demand for electronic products, major manufacturers also focus on enhancing the market competitiveness of their brands.

For instance, packaging structures are common electronic components. Therefore, the optimization of quality of packaging structures at low cost is undoubtedly a key issue that various manufacturers highly concern.

### SUMMARY

A technical aspect of the present disclosure is to provide a package structure module, which can effectively enhance the structural strength and reduce the cost of production.

According to an embodiment of the present disclosure, a package structure includes a substrate, a chip, a first electrically conductive piece and a second electrically conductive piece. The chip is disposed on the substrate. The first electrically conductive piece includes a first electrically conductive portion and at least one first pin. The first pin is connected with the first electrically conductive portion. The first electrically conductive portion is connected with the chip. The first pin is away from the chip. The second electrically conductive piece includes a second electrically conductive portion and at least one second pin. The second pin is connected with the second electrically conductive portion. The second electrically conductive portion is connected with the chip. The second pin is away from the chip. At least one of the first electrically conductive piece and the second electrically conductive piece is an integrally formed structure.

In one or more embodiments of the present disclosure, the first electrically conductive piece and the second electrically conductive piece are spaced apart from each other.

In one or more embodiments of the present disclosure, when the first electrically conductive piece is an integrally formed structure, the first electrically conductive portion has a flattened shape.

In one or more embodiments of the present disclosure, the first electrically conductive portion has a first surface, a second surface and at least one through hole. The first surface and the second surface are opposite to each other. The through hole is communicated with the first surface and the second surface. The second surface at least partially abuts against the chip.

In one or more embodiments of the present disclosure, the first electrically conductive portion includes a first subsidiary electrically conductive portion and a second subsidiary electrically conductive portion. The second subsidiary electrically conductive portion is connected between the first subsidiary electrically conductive portion and the first pin. The first subsidiary electrically conductive portion has a first width. The second subsidiary electrically conductive portion has a second width. The first width and the second width are different from each other.

In one or more embodiments of the present disclosure, a quantity of the first pin and a quantity of the second pin are different from each other.

In one or more embodiments of the present disclosure, when the second electrically conductive piece is an integrally formed structure, the second electrically conductive portion has a flattened shape.

In one or more embodiments of the present disclosure, the second electrically conductive portion has a third width. The third width decreases towards a direction away from the second pin.

In one or more embodiments of the present disclosure, the substrate is an insulator.

According to another embodiment of the present disclosure, a package structure includes a substrate, a chip, a first electrically conductive piece and a second electrically conductive piece. The chip is disposed on the substrate. The first electrically conductive piece includes a first electrically conductive portion and at least one first pin. The first pin is connected with the first electrically conductive portion. The first electrically conductive portion is connected with the chip. The first pin is away from the chip. The first electrically conductive portion and the first pin are an integrally formed structure. The second electrically conductive piece includes a second electrically conductive portion and at least one second pin. The second pin is connected with the second electrically conductive portion. The second electrically conductive portion is connected with the chip. The second pin is away from the chip. The second electrically conductive portion and the second pin are an integrally formed structure.

The above-mentioned embodiments of the present disclosure have at least the following advantages:
(1) Since the first electrically conductive piece and/or the second electrically conductive piece are integrally formed structures, the structural strength of the package structure is effectively enhanced.
(2) Since the first electrically conductive portion of the first electrically conductive piece and the second electrically conductive portion of the second electrically conductive piece are respectively in direct contact with the chip, cables are not required to be additionally disposed between the first electrically conductive piece and the chip and between the second electrically conductive piece and the chip for electrical connection. Thus, there is a significant saving of assembly time and the production cost is reduced.
(3) Since the first electrically conductive piece and/or the second electrically conductive piece are integrally formed structures, the power consumption during electrical transmission is effectively reduced.

### BRIEF DESCRIPTION OF THE DRAWINGS

The disclosure can be more fully understood by reading the following detailed description of the embodiments, with reference made to the accompanying drawings as follows:

FIG. 1 is a top view of a package structure according to an embodiment of the present disclosure;

FIG. 2 is a sectional view along the sectional line A-A of FIG. 1; and

FIG. 3 is a sectional view along the sectional line B-B of FIG. 1.

### DETAILED DESCRIPTION

Drawings will be used below to disclose embodiments of the present disclosure. For the sake of clear illustration, many practical details will be explained together in the description below. However, it is appreciated that the practical details should not be used to limit the claimed scope. In other words, in some embodiments of the present disclosure, the practical details are not essential. Moreover, for the sake of drawing simplification, some customary structures and elements in the drawings will be schematically shown in a simplified way. Wherever possible, the same reference numbers are used in the drawings and the description to refer to the same or like parts.

Unless otherwise defined, all terms (including technical and scientific terms) used herein have the same meanings as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

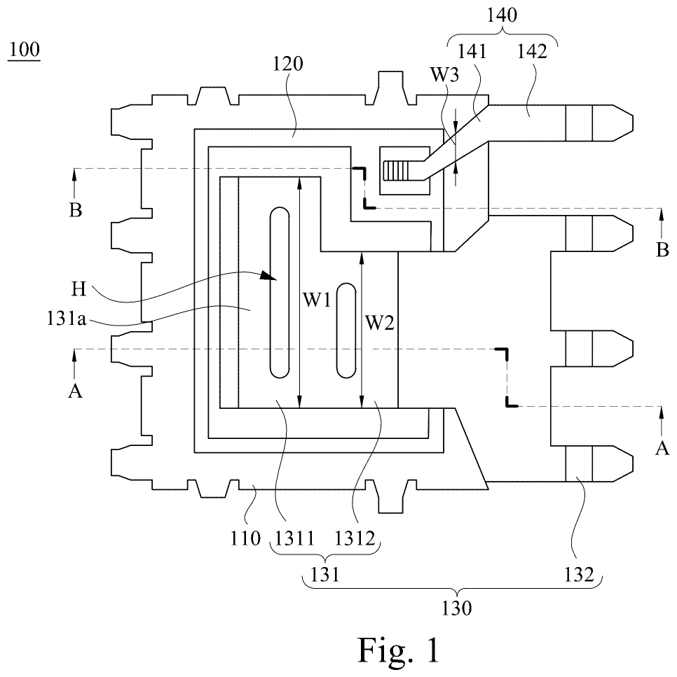

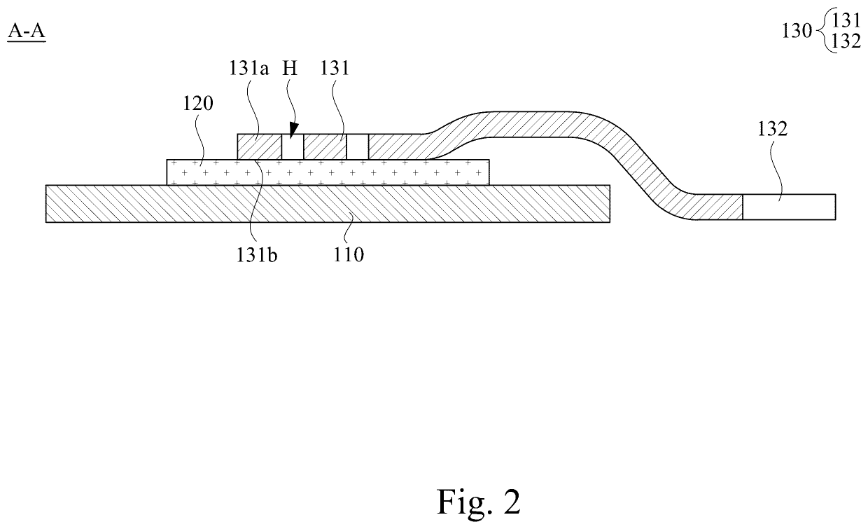

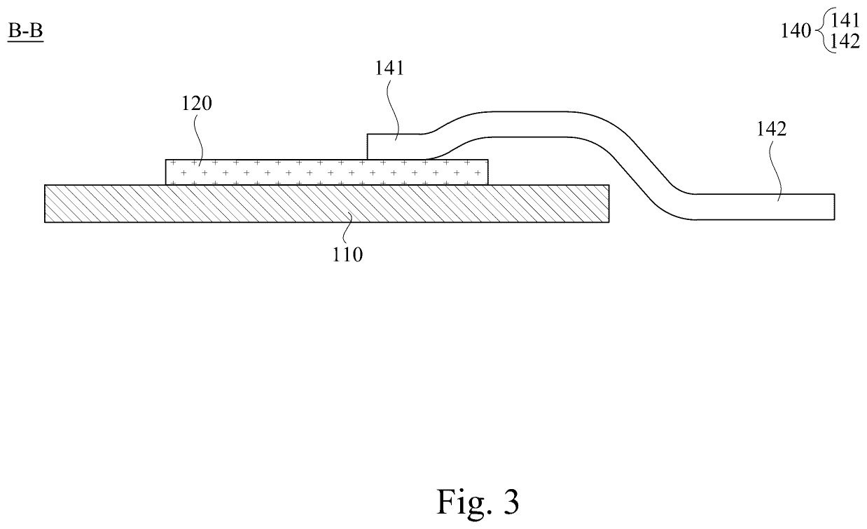

Reference is made to FIGS. 1-3. FIG. 1 is a top view of a package structure 100 according to an embodiment of the present disclosure. FIG. 2 is a sectional view along the sectional line A-A of FIG. 1. FIG. 3 is a sectional view along the sectional line B-B of FIG. 1. In this embodiment, as shown in FIGS. 1-3, a package structure 100 includes a substrate 110, a chip 120, a first electrically conductive piece 130 and a second electrically conductive piece 140. The chip 120 is disposed on the substrate 110, and the substrate 110 is substantially an insulator. The first electrically conductive piece 130 includes a first electrically conductive portion 131 and at least one first pin 132. The first pin 132 is connected with the first electrically conductive portion 131. The first electrically conductive portion 131 is connected with the chip 120. The first pin 132 is away from the chip 120. The second electrically conductive piece 140 includes a second electrically conductive portion 141 and at least one second pin 142. The second pin 142 is connected with the second electrically conductive portion 141. The second electrically conductive portion 141 is connected with the chip 120. The second pin 142 is away from the chip 120.

In this embodiment, as shown in FIG. 1, both of the first electrically conductive piece 130 and the second electrically conductive piece 140 are integrally formed structures. This means the first electrically conductive portion 131 and the first pin 132 are made from a single piece of material, while the second electrically conductive portion 141 and the second pin 142 are also made from a single piece of material. In other embodiments, according to the actual situation, at least one of the first electrically conductive piece 130 and the second electrically conductive piece 140 is an integrally formed structure. In other words, when first electrically conductive piece 130 is an integrally formed structure, the second electrically conductive piece 140 is not an integrally formed structure. On the contrary, when second electrically conductive piece 140 is an integrally formed structure, the first electrically conductive piece 130 is not an integrally formed structure.

To be specific, since the first electrically conductive piece 130 and/or the second electrically conductive piece 140 are integrally formed structures, the structural strength of the package structure 100 is effectively enhanced.

Moreover, since the first electrically conductive portion 131 of the first electrically conductive piece 130 and the second electrically conductive portion 141 of the second electrically conductive piece 140 are respectively in direct contact with the chip 120, cables are not required to be additionally disposed between the first electrically conductive piece 130 and the chip 120 and between the second electrically conductive piece 140 and the chip 120 for electrical connection. Thus, there is a significant saving of assembly time and the production cost is reduced.

Furthermore, since the first electrically conductive piece 130 and/or the second electrically conductive piece 140 are integrally formed structures, the power consumption during electrical transmission is effectively reduced.

In addition, as shown in FIG. 1, the first electrically conductive piece 130 and the second electrically conductive piece 140 are spaced apart from each other. The means the first electrically conductive piece 130 and the second electrically conductive piece 140 do not directly contact with each other.

As mentioned above, in this embodiment, as shown in FIG. 1, both of the first electrically conductive piece 130 and the second electrically conductive piece 140 are integrally formed structures. Under this situation, as shown in FIGS. 2-3, the first electrically conductive portion 131 of the first electrically conductive piece 130 and the second electrically conductive portion 141 of the second electrically conductive piece 140 respectively have a flattened shape.

Moreover, in practical applications, a quantity of the first pin 132 and a quantity of the second pin 142 are different from each other. For example, as shown in FIG. 1, the quantity of the first pin 132 is three, while the quantity of the second pin 142 is one. In other embodiments, according to the actual situation, the quantity of the first pin 132 and the quantity of the second pin 142 are equal to each other.

Furthermore, as shown in FIG. 1, the first electrically conductive portion 131 includes a first subsidiary electrically conductive portion 1311 and a second subsidiary electrically conductive portion 1312. The second subsidiary electrically conductive portion 1312 is connected between the first subsidiary electrically conductive portion 1311 and the first pins 132. The first subsidiary electrically conductive portion 1311, the second subsidiary electrically conductive portion 1312 and the first pins 132 are an integrally formed structure. This means the first subsidiary electrically conductive portion 1311, the second subsidiary electrically conductive portion 1312 and the first pins 132 are made from a single piece of material. In this embodiment, the first subsidiary electrically conductive portion 1311 has a first width W1. The second subsidiary electrically conductive portion 1312 has a second width W2. The first width W1 of the first subsidiary electrically conductive portion 1311 and the second width W2 of the second subsidiary electrically conductive portion 1312 are different from each other. For example, as shown in FIG. 1, the first width W1 of the first subsidiary electrically conductive portion 1311 is larger than the second width W2 of the second subsidiary electrically conductive portion 1312. However, this does not intend to limit the present disclosure. In other embodiments, according to the actual situation, the first width W1 of the first subsidiary electrically conductive portion 1311 is less than the second width W2 of the second subsidiary electrically conductive portion 1312.

Moreover, as shown in FIG. 1, the second electrically conductive portion 141 has a third width W3. In this embodiment, the third width W3 of the second electrically conductive portion 141 at least partially decreases towards a direction away from the second pin 142.

In practical applications, as shown in FIGS. 1-2, the first electrically conductive portion 131 has a first surface 131a, a second surface 131b and at least one through hole H. The first surface 131a and the second surface 131b are opposite to each other. The through hole H is communicated with the first surface 131a and the second surface 131b. The first surface 131a is away from the chip 120. The second surface 131b at least partially abuts against the chip 120.

In conclusion, the aforementioned embodiments of the present disclosure have at least the following advantages:
(1) Since the first electrically conductive piece and/or the second electrically conductive piece are integrally formed structures, the structural strength of the package structure is effectively enhanced.
(2) Since the first electrically conductive portion of the first electrically conductive piece and the second electrically conductive portion of the second electrically conductive piece are respectively in direct contact with the chip, cables are not required to be additionally disposed between the first electrically conductive piece and the chip and between the second electrically conductive piece and the chip for electrical connection. Thus, there is a significant saving of assembly time and the production cost is reduced.
(3) Since the first electrically conductive piece and/or the second electrically conductive piece are integrally formed structures, the power consumption during electrical transmission is effectively reduced.

Although the present disclosure has been described in considerable detail with reference to certain embodiments thereof, they are not intended to limit the present disclosure. Any person skilled in the art may make various modifications and refinements without departing from the spirit and scope of the present disclosure. Therefore, the scope of protection of the present disclosure shall be determined by the appended claims.

What is claimed is:

1. A package structure, comprising:
a substrate;
a chip disposed on the substrate;
a first electrically conductive piece comprising a first electrically conductive portion and at least one first pin connected with the first electrically conductive portion, the first electrically conductive portion connecting with the chip, the first pin being away from the chip; and
a second electrically conductive piece comprising a second electrically conductive portion and at least one second pin connected with the second electrically conductive portion, the second electrically conductive portion connecting with the chip, the second pin being away from the chip,
wherein at least one of the first electrically conductive piece and the second electrically conductive piece is an integrally formed structure.

2. The package structure of claim 1, wherein the first electrically conductive piece and the second electrically conductive piece are spaced apart from each other.

3. The package structure of claim 1, wherein when the first electrically conductive piece is an integrally formed structure, the first electrically conductive portion has a flattened shape.

4. The package structure of claim 3, wherein the first electrically conductive portion has a first surface, a second surface and at least one through hole, the first surface and the second surface are opposite to each other, the through hole communicates with the first surface and the second surface, the second surface at least partially abuts against the chip.

5. The package structure of claim 3, wherein the first electrically conductive portion comprises a first subsidiary electrically conductive portion and a second subsidiary electrically conductive portion, the second subsidiary electrically conductive portion is connected between the first subsidiary electrically conductive portion and the first pin, the first subsidiary electrically conductive portion has a first width, the second subsidiary electrically conductive portion has a second width, the first width and the second width are different from each other.

6. The package structure of claim 1, wherein a quantity of the first pin and a quantity of the second pin are different from each other.

7. The package structure of claim 1, wherein when the second electrically conductive piece is an integrally formed structure, the second electrically conductive portion has a flattened shape.

8. The package structure of claim 7, wherein the second electrically conductive portion has a third width, the third width decreases towards a direction away from the second pin.

9. The package structure of claim 1, wherein the substrate is an insulator.

10. A package structure, comprising:
a substrate;
a chip disposed on the substrate;
a first electrically conductive piece comprising a first electrically conductive portion and at least one first pin connected with the first electrically conductive portion, the first electrically conductive portion connecting with the chip, the first pin being away from the chip, the first electrically conductive portion and the first pin are an integrally formed structure; and
a second electrically conductive piece comprising a second electrically conductive portion and at least one second pin connected with the second electrically conductive portion, the second electrically conductive portion connecting with the chip, the second pin being away from the chip, the second electrically conductive portion and the second pin are an integrally formed structure.
